(19) United States
(12) Patent Application Publication
(10) Pub. No.: US 2013/0135953 A1
(43) Pub. Date: May 30, 2013

(54) SEMICONDUCTOR MEMORY DEVICE

(71) Applicant: Osamu Hirabayashi, Suginami-Ku (JP)

(72) Inventor: Osamu Hirabayashi, Suginami-Ku (JP)

(73) Assignee: KABUSHIKI KAISHA TOSHIBA, Tokyo (JP)

(21) Appl. No.: 13/422,894

(22) Filed: Mar. 16, 2012

(30) Foreign Application Priority Data
Nov. 30, 2011 (JP) 2011-262022

(51) Int. Cl. G11C 29/00

(52) U.S. Cl. 365/201

(57) ABSTRACT

According to an embodiment, provided are a memory cell configured to store data, a word line configured to select the memory cell in each row, a bit line configured to transfer a signal read from a memory cell in each column, a self-test circuit configured to test an operation of the memory cell, and a regulator configured to set a voltage of the word line or a cell power supply voltage of the memory cell to accelerate a disturb failure of the memory cell, based on an acceleration command from the self-test circuit.

### CROSS-REFERENCE TO RELATED APPLICATIONS

This application is based upon and claims the benefit of priority from Japanese Patent Application No. 2011-262022, filed on Nov. 30, 2011; the entire contents of which are incorporated herein by reference.

### FIELD

Embodiments described relate generally to semiconductor memory devices.

### BACKGROUND

In an SRAM, the random fluctuation of the characteristics of each transistor of a memory cell increases with the miniaturization of the memory cell. Accordingly, the operation margin of the SRAM is reduced, and the operation voltage is difficult to be lowered, or the operation speed is reduced.

### BRIEF DESCRIPTION OF THE DRAWINGS

FIG. 1 is a block diagram illustrating a schematic configuration of a semiconductor memory device according to an embodiment;

FIG. 2 is a block diagram illustrating a schematic configuration of an SRAM of FIG. 1;

FIG. 3 is a circuit diagram illustrating an example of a schematic configuration of a regulator of FIG. 1;

FIG. 4 is a diagram illustrating a relation between a disturb failure occurrence rate and a potential difference ΔV2 between a cell power supply voltage and a word line voltage;

FIG. 5 is a diagram illustrating a relation between a memory capacity and a disturb failure occurrence rate; and

FIG. 6 is a diagram illustrating a relation between a temperature and a disturb failure occurrence rate.

### DETAILED DESCRIPTION

Semiconductor memory devices according to embodiments include a self-test circuit configured to test an operation of a memory cell, and a regulator configured to set a voltage of a word line or a cell power supply voltage of the memory cell to accelerate a disturb failure of the memory cell, based on an acceleration command from the self-test circuit.

Hereinafter, semiconductor memory devices according to embodiments will be described with reference to the drawings. However, the present invention is not limited to these embodiments.

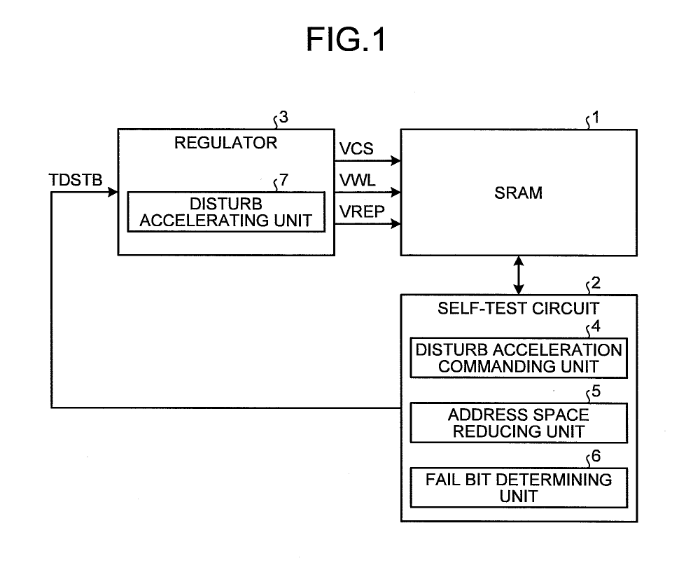

FIG. 1 is a block diagram illustrating a schematic configuration of a semiconductor memory device according to an embodiment.

In FIG. 1, a semiconductor memory device includes an SRAM 1, a self-test circuit 2, and a regulator 3. The SRAM 1 includes a memory cell configured to store data, a word line configured to select the memory cell in each row, and a bit line configured to transfer a signal read from the memory cell in each column. The self-test circuit 2 may test an operation of the SRAM 1. The regulator 3 may set a word line voltage VWL of the SRAM 1 and a cell power supply voltage VCS of the memory cell.

Herein, the self-test circuit 2 includes a disturb acceleration commanding unit 4, an address space reducing unit 5, and a fail bit determining unit 6. The regulator 3 includes a disturb accelerating unit 7.

The disturb acceleration commanding unit 4 may output a memory cell disturb acceleration command. The address space reducing unit 5 may reduce an address space of the memory cell to be tested by the self-test circuit 2. The fail bit determining unit 6 may determine a fail bit of the memory cell tested by the self-test circuit 2. The disturb accelerating unit 7 may set a word line voltage VWL and a cell power supply voltage VCS to accelerate a disturb failure of the memory cell, based on an acceleration command TDSTB from the disturb acceleration commanding unit 4.

In a screening test mode, the acceleration command TDSTB is output from the disturb acceleration commanding unit 4 to the regulator 3. The disturb accelerating unit 7 sets the word line voltage VWL and the cell power supply voltage VCS to accelerate a disturb failure of the memory cell, and the self-test circuit 2 tests an operation of the SRAM 1. In order to accelerate a disturb failure of the memory cell, for example, a difference between the word line voltage VWL and the cell power supply voltage VCS may be set to be greater than that in a general use mode.

In the test of an operation of the SRAM 1, for example, after writing into the memory cell is performed, reading from the memory cell is performed. The fail bit determining unit 6 may test the memory cell by determining whether or not write data and read data are identical to each other. At this time, the address space reducing unit 5 reduces an address space, so that only some of the memory cells of the SRAM 1 are tested. Also, it is preferable that a degenerate address is selected such that accessed memory cells are distributed spatially uniformly. Accordingly, uniform sampling in the entire memory region of the SRAM 1 can be realized, and the bias of the characteristics of screening-tested memory cells can be reduced. Also, for example, a method of degenerating a lower address may be used as a method of uniformly reducing an address space.

In the screening test, if it is expected that a disturb failure will occur frequently, the disturb failure can be reduced by lowering the word line voltage VWL in a general use mode. Thereafter, a test may be performed on the entire address space, and redundancy repair may be performed when a failure has occurred.

Herein, in the screening test, a test time can be reduced by reducing the address space. Also, even when the address space is reduced, the detection sensitivity of the disturb failure can be compensated by accelerating the disturb failure of the memory cell, and a random fluctuation of the characteristics of each transistor of the memory cell can be efficiently tested.

Also, when the word line voltage VWL can be set to a plurality of levels, the word line voltage VWL may be set to pass the screening test by repeatedly performing the screening test by sequentially lowering the word line voltage VWL.

Also, in the test of the entire address space after the screening test, when a failure in the number of bits incapable of redundancy repair is detected, a test of the entire address space may be repeated by further lowering the word line voltage VWL. By doing so, a disturb failure incapable of being completely screened in the screening test can be repaired.

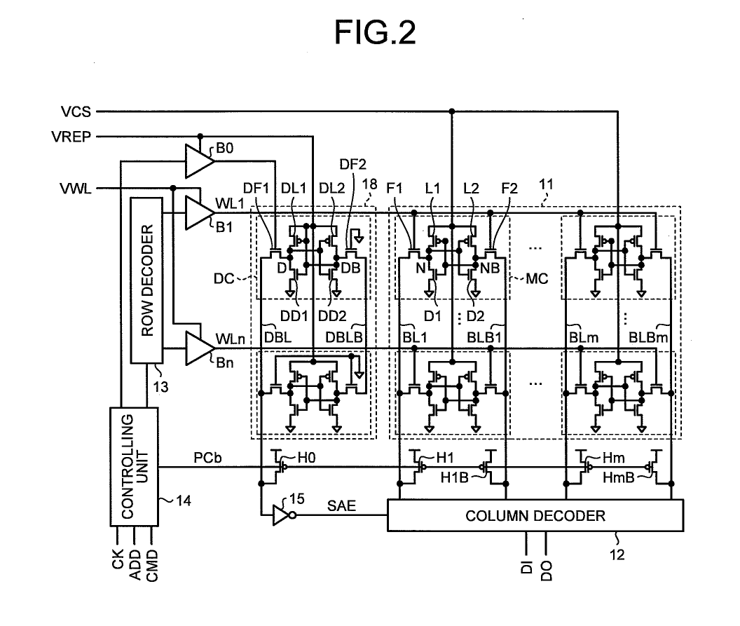

FIG. 2 is a block diagram illustrating a schematic configuration of the SRAM 1 of FIG. 1.

In FIG. 2, the semiconductor memory device includes a memory cell array 11, a column decoder 12, a row decoder 13, a controlling unit 14, an inverter 15, and a dummy cell array 18.

In the memory cell array 11, memory cells MC are arranged in a matrix form in a row direction and a column direction. Also, the memory cells MC may store data complementarily and may constitute, for example, an SRAM.

In the memory cell array 11, word lines WL1 to WLn (n: a positive integer) are provided in each row to transfer signals for row selection of the memory cells MC. Also, in the memory cell array 11, bit lines BL1 to BLm and BLB1 to BLBm (m: a positive integer) are provided in each column to transfer data exchanged between the memory cells MC.

The memory cells MC in the same row are connected in common through each of the word lines WL1 to WLn. Also, the memory cells MC in the same column are connected in common through each of the bit lines BL1 to BLm and BLB1 to BLBm. Also, in a read/write mode for the memory cells MC, the respective bit lines BL1 to BLm and BLB1 to BLBm may be operated complementarily to each other. For example, in a read/write mode for the memory cell MC, the bit line BLBm may be set to a low level when the bit line BLm is set to a high level, and the bit line BLBm may be set to a high level when the bit line BLm is set to a low level. Also, the bit lines BLm and BLBm may be together precharged to a high level before the read/write mode.

Herein, the memory cell MC includes a pair of drive transistors D1 and D2, a pair of load transistors L1 and L2, and a pair or transfer transistors F1 and F2. Also, P-channel field effect transistors may be used as the load transistors L1 and L2, and N-channel field effect transistors may be used as the drive transistors D1 and D2 and the transfer transistors F1 and F2.

The drive transistor D1 and the load transistor L1 are connected in series to each other to constitute a CMOS inverter, and the drive transistor D2 and the load transistor L2 are connected in series to each other to constitute a CMOS inverter. The outputs and inputs of a pair of the CMOS inverters are cross-coupled with each other to constitute a flip-flop. The word lines WL1 to WLn are connected to the gates of the transfer transistors F1 and F2 in each row.

Herein, a connection point between the drain of the drive transistor D1 and the drain of the load transistor L1 may constitute a storage node N, and a connection point between the drain of the drive transistor D2 and the drain of the load transistor L2 may constitute a storage node NB.

Also, each of the bit lines BL1 to BLm is connected to the storage node N through the transfer transistor F1. Also, each of the bit lines BLB1 to BLBm is connected to the storage node NB through the transfer transistor F2.

Also, precharge transistors H1 to Hm are connected respectively to the bit lines BL1 to BLm, and precharge transistors H1B to HmB are connected respectively to the bit lines BLB1 to BLBm. Also, P-channel field effect transistors may be used as the precharge transistors H1-Hm and H1B to HmB. Also, the cell power supply voltage VCS is supplied to each of the memory cells MC. In an example of FIG. 2, the cell power supply voltage VCS is supplied to the sources of the load transistors L1 and L2.

Dummy cells DC are arranged in the dummy cell array 18. The dummy cell DC may simulate an operation of the memory cell MC, and may be configured in the same way as the memory cell MC. Herein, in the dummy cell array 18, in order to reduce the influence of a characteristic fluctuation by the manufacturing fluctuation when used alone, a plurality of dummy cells DC may be provided to average a random fluctuation. Also, the dummy cell array 18 includes dummy bit lines DBL and DBLB that transfer signals read from the dummy cells DC.

Herein, the dummy cell DC includes a pair of dummy drive transistors DD1 and DD2, a pair of dummy load transistors DL1 and DL2, and a pair or dummy transfer transistors DF1 and DF2. Also, P-channel field effect transistors may be used as the dummy load transistors DL1 and DL2, and N-channel field effect transistors may be used as the dummy drive transistors DD1 and DD2 and the dummy transfer transistors DF1 and DF2.

The dummy drive transistor DD1 and the dummy load transistor DL1 are connected in series to each other to constitute a CMOS inverter, and the dummy drive transistor DD2 and the dummy load transistor DL2 are connected in series to each other to constitute a CMOS inverter. The outputs and inputs of a pair of the CMOS inverters are cross-coupled with each other to constitute a flip-flop.

Herein, a connection point between the drain of the dummy drive transistor DD1 and the drain of the dummy load transistor DL1 may constitute a dummy node D, and a connection point between the drain of the dummy drive transistor DD2 and the drain of the dummy load transistor DL2 may constitute a dummy node DB.

Also, the dummy node D is connected to the dummy bit line DBL through the dummy transfer transistor DF1, and the dummy node DB is connected to the dummy bit line DBLB through the dummy transfer transistor DF2. Also, a precharge transistor H0 is connected to the dummy bit line DBL. Also, a P-channel field effect transistor may be used as the precharge transistor H0.

Also, in some dummy cells DC of the dummy cell array 18, the controlling unit 14 is connected through a buffer B0 to the gate of the dummy transfer transistor DF1, the gate of the dummy transfer transistor DF2 is grounded, and the dummy node D is connected to the source of the dummy load transistor DL1. In the other dummy cells DC of the dummy cell array 18, the gates of the dummy transfer transistors DF1 and DF2 are grounded. Also, a dummy cell power supply voltage VREP is supplied to each of the dummy cells DC. In an example of FIG. 2, the dummy cell power supply voltage VREP is supplied to the sources of the dummy load transistors DL1 and DL2.

The column decoder 12 may select a column of the memory cell MC designated by a column address. Herein, the column decoder 12 may include a sense amplifier circuit that detects data stored in the memory cell MC, based on signals read from the memory cell MC to the bit lines BL and BLB. Read data DO may be output through the sense amplifier circuit. Also, the column decoder 12 may write data into a select cell by complementarily changing the potentials of the bit lines BL1 to BLm and BLB1 to BLBm in a select row, based on write data DI. The row decoder 13 may select a row of the memory cell MC designated by a row address. Buffers B1 to Bn may drive the respective word lines WL1 to WLn, based on the row selection by the row decoder 13. Herein, the word line voltage VWL is supplied as a power supply voltage of the buffers B1 to Bn.

The controlling unit 14 may control the timing of driving the column decoder 12, the row decoder 13, the buffer B0, and the precharge transistors H0 to Hm and H1B to HmB, based on an address ADD and a command CMD. The inverter 15 may activate a sense amplifier enable signal SAE, based on the potential of the dummy bit line DBL.

In a screening test mode, an acceleration command TDSTB is output from the disturb acceleration commanding unit 4 to the regulator 3. The disturb accelerating unit 7 sets the word line voltage VWL and the cell power supply voltage VCS to accelerate a disturb failure of the memory cell, and the self-test circuit 2 tests an operation of the SRAM 1. In order to accelerate a disturb failure of the memory cell, for example, a difference between the word line voltage VWL and the cell power supply voltage VCS may be set to be greater than that in a general use mode.

In the test of an operation of the SRAM 1, for example, after writing into the memory cell is performed, reading from the memory cell is performed. The fail bit determining unit 6 may test the memory cell by determining whether or not write data and read data are identical to each other. At this time, the address space reducing unit 5 reduces an address space, so that only some of the memory cells of the SRAM 1 are tested.

The word line voltage VWL and the cell power supply voltage VCS in a general use mode after product shipment may be set based on the screening test result. Herein, for example, a power save mode and a disturb margin improvement mode may be provided as a method of setting the word line voltage VWL and the cell power supply voltage VCS. In the power save mode, both the word line voltage VWL and the cell power supply voltage VCS may be set to be lower when a read speed of the memory cell MC is high than when the read speed of the memory cell MC is low. In the disturb margin improvement mode, the word line voltage VWL may be set to be lower when the read speed is high than when the read speed is low, with the cell power supply voltage VCS being constant. Also, the power save mode or the disturb margin improvement mode may be selected according to a fluctuation in the characteristics of the memory cell MC. The fluctuation in the characteristics of the memory cell MC may be estimated from a disturb failure occurrence rate of the memory cell MC.

When the number of fail bits exceeds a predetermined value, the fail bit determining unit 6 of FIG. 1 may determine that the disturb failure occurrence rate of the memory cell is high, and when the number of fail bits is equal to or smaller than the predetermined value, the fail bit determining unit 6 may determine that the disturb failure occurrence rate of the memory cell is low. For example, when fail bits incapable of being repaired by redundancy are detected, the fail bit determining unit 6 may determine it as a failure. In this way, the result of disturb failure screening may not be affected by a fail bit caused by a defect capable of redundancy repair.

The test result of the self-test circuit 2 of FIG. 1 is provided to the regulator 3. The regulator 3 sets the word line voltage VWL and the cell power supply voltage VCS before performing a read/write operation of the memory cell MC. The regulator 3 sets the dummy cell power supply voltage VREP in conjunction with the cell power supply voltage VCS. At this time, the dummy cell power supply voltage VREP may be set to a potential that is lower than the word line voltage VWL and the cell power supply voltage VCS by a predetermined voltage. This is done to be able to reproduce the characteristics of the memory cell MC having the highest threshold voltage (the smallest read current), by considering the fact that the characteristics of the memory cell MC randomly fluctuates. The dummy cell power supply voltage VREP may be set to a value that is lower by a predetermined voltage corresponding to the random fluctuation.

When generally used after product shipment, in a standby mode, a precharge signal PCb is activated by the controlling unit 4, so that the precharge transistors H0 to Hm and H1B to HmB are turned on and the dummy bit line DBL and the bit lines BL1 to BLm and BLB1 to BLBm are precharged to a high level. At this time, the potential of the dummy bit line DBL is inverted by the inverter 15, so that the sense amplifier enable signal SAE is maintained at a low level and the sense amplifier circuit is deactivated.

Also, in a read mode, the output of the buffer B0 may be initiated at the timing of initiating the word lines WL1 to WLn row-selected by the row decoder 13. For example, when ‘0’ is stored at the storage node N of a select cell and ‘1’ is stored at the storage node NB, the word lines WL1 to WLn of a select row are initiated, so that the transfer transistor F1 is turned on and a cell current flows in the bit lines BL1 to BLm of a select column. Accordingly, the potential of the bit lines BL1 to BLm of a select column is reduced gradually.

Also, since the output of the buffer B0 is initiated, the dummy transfer transistor DF1 is turned on and a dummy current flows in the dummy bit line DBL. Accordingly, the potential of the dummy bit line DBL is reduced gradually. Herein, the dummy bit line DBL simulates the bit lines BL1 to BLm, so that a change state of the potential of the bit lines BL1 to BLm can be simulated by the dummy bit line DBL.

When the potential of the dummy bit line DBL reaches the threshold value of the inverter 15, the sense amplifier enable signal SAE is initiated to activate the sense amplifier circuit. In the sense amplifier circuit, data stored in the memory cell MC is detected on the basis of a signal transmitted through the bit lines BL1 to BLm, and it is output as read data DO.

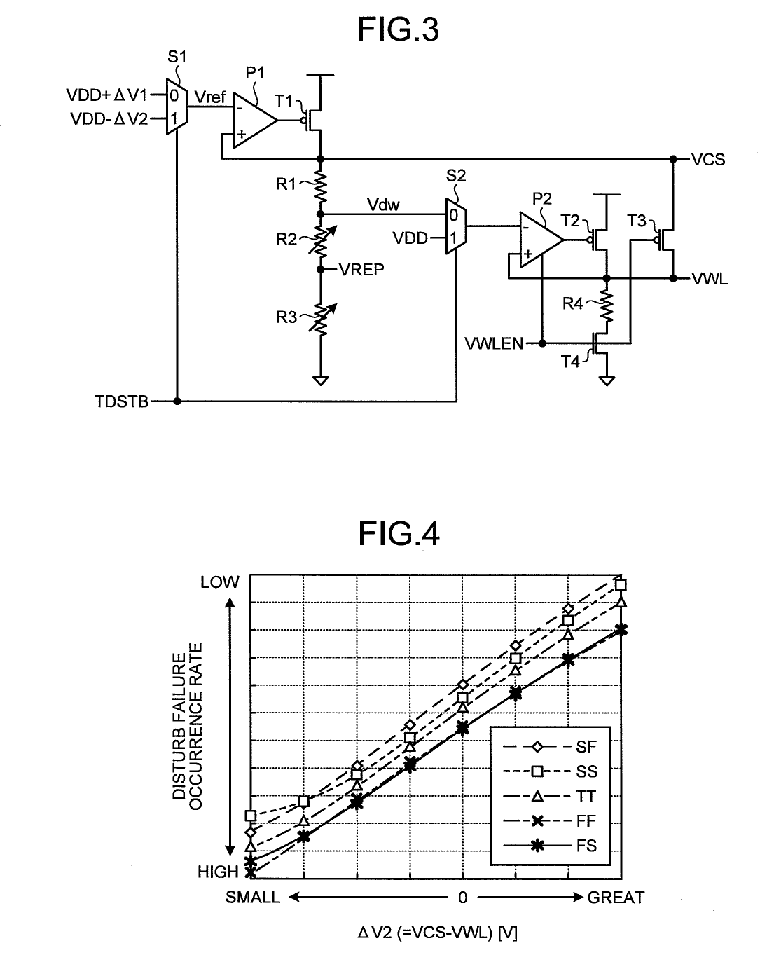

FIG. 3 is a circuit diagram illustrating an example of a schematic configuration of the regulator of FIG. 1. In the regulator 3, in a general use mode, the cell power supply voltage VCS is set to be higher than a logical power supply voltage VDD, and the word line voltage VWL is set to be equal to or lower than the cell power supply voltage VCS. In a screening test mode, the cell power supply voltage VCS is set to be lower than the logical power supply voltage VDD, and the cell power supply voltage VWL is set to be equal to the logical power supply voltage VDD. Also, the dummy cell power supply voltage VREP is set to a potential that is lower than the cell power supply voltage VCS by a predetermined voltage.

In other words, in FIG. 3, the regulator 3 includes transistors T1 to T4, comparators P1 and P2, selectors S1 and S2, resistors R1 and R4, and variable resistors R2 and R3. Also, P-channel field effect transistors may be used as the transistors T1 to T3, and an N-channel field effect transistor may be used as the transistor T4.

In a general use mode, the acceleration command TDSTB is deactivated. At this time, the selector S1 selects VDD+ΔV1 as a reference voltage Vref. Also, the selector S2 selects a dropped voltage Vdw dropped by the resistor R1.

Also, in the disturb margin improvement mode, an enable signal VWLEN is activated to turn off the transistor T3 and turn on the transistor T4.

The comparator P1 compares the reference voltage Vref and the cell power supply voltage VCS. The transistor Ti is turned on/off on the basis of the comparison result, so that the cell power supply voltage VCS is set to be equal to the reference voltage Vref. Also, the cell power supply voltage VCS is divided by the resistor R1 and the variable resistors R2 and R3, and the dummy cell power supply voltage VREP is set to be lower than the cell power supply voltage VCS.

Also, the comparator P2 compares the dropped voltage Vdw with the word line voltage VWL. The transistor T2 is turned on/off on the basis of the comparison result, so that the word line voltage VWL is set to be equal to the dropped voltage Vdw.

Also, in a general use mode and in the power save mode, the enable signal VWLEN is deactivated to turn on the transistor T3 and turn off the transistor T4. Accordingly, the word line voltage VWL is set to be equal to the cell power supply voltage VCS.

Also, in the screening test mode, the acceleration command TDSTB is activated. At this time, the selector S1 selects VDD−ΔV2 as the reference voltage Vref. Also, the selector S2 selects the logical power supply voltage VDD.

The comparator P1 compares the reference voltage Vref and the cell power supply voltage VCS. The transistor T1 is turned on/off on the basis of the comparison result, so that the cell power supply voltage VCS is set to be equal to the reference voltage Vref. Also, the cell power supply voltage VCS is divided by the resistor R1 and the variable resistors R2 and R3, and the dummy cell power supply voltage VREP is set to be lower than the cell power supply voltage VCS.

Also, the comparator P2 compares the logical power supply voltage VDD with the word line voltage VWL. The transistor T2 is turned on/off on the basis of the comparison result, so that the word line voltage VWL is set to be equal to the logical power supply voltage VDD.

FIG. 4 is a diagram illustrating a relation between a disturb failure occurrence rate and a potential difference ΔV2 between a cell power supply voltage and a word line voltage. In FIG. 4, SF represents a condition that the N-channel field effect transistor is slow and the P-channel field effect transistor is fast. SS represents a condition that the N-channel field effect transistor and the P-channel field effect transistor are slow. TT represents a condition that the N-channel field effect transistor and the P-channel field effect transistor are typical. FF represents a condition that the N-channel field effect transistor and the P-channel field effect transistor are fast. FS represents a condition that the N-channel field effect transistor is fast and the P-channel field effect transistor is slow.

In FIG. 4, the disturb failure occurrence rate changes in proportion to a change in the potential difference ΔV2. Accordingly, a disturb failure can be randomly accelerated by changing the potential difference ΔV2. For example, when ΔV2 is set to 0.1 V (ΔV2=0.1V), the disturb failure is accelerated by 2.4σ. Herein, a is a standard deviation of the disturb failure.

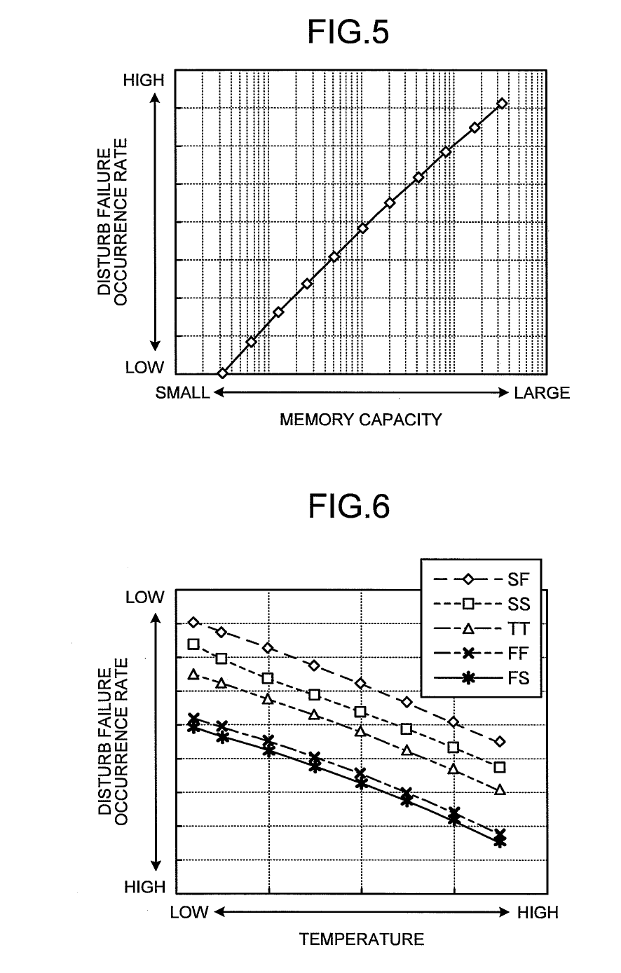

FIG. 5 is a diagram illustrating a relation between a memory capacity and a disturb failure occurrence rate.

In FIG. 5, the disturb failure occurrence rate changes in proportion to a change in the memory capacity. For example, in an SRAM with a capacity of 32 Mb, when only 128 Kb memory cells are tested, a difference in the failure occurrence rate caused by a capacity difference is about 1.1σ.

Accordingly, when an address space corresponding to a test target is reduced, the disturb failure occurrence rate is reduced. In this case, by referring to FIGS. 4 and 5, it may be estimated to what extent the potential difference ΔV2 needs to be set in order to provide a uniform disturb failure occurrence rate when the address space is reduced.

FIG. 6 is a diagram illustrating a relation between a temperature and a disturb failure occurrence rate.

In FIG. 6, the disturb failure occurrence rate increases with an increase in the temperature. If the maximum use temperature of this chip was 125° C. and the test temperature in shipment was 25° C., a difference in the disturb failure occurrence rate according to the temperature conditions is about 1.1σ.

From the above, for example, when only the 128 Kb capacity is tested at 25° C. instead of testing the entire 32 Mb capacity at the worst temperature condition (125° C.), since the disturb failure occurrence rate is reduced by 1.1σ+1.1σ=2.2σ, the failure detection sensitivity by the screening test is reduced.

In this case, since the disturb failure occurrence rate can be accelerated by 2.4σ by setting VWL to VCS+0.1 V (VWL=VCS+0.1 V), the reduction of the failure detection sensitivity by the screening test can be compensated. Since the execution time of the memory test is proportional to the number of words, the memory test execution time can be reduced to 1/256 by accessing only 128 Kb by degenerating the address space.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell configured to store data;
a word line configured to select the memory cell in each row;
a bit line configured to transfer a signal read from a memory cell in each column;
a self-test circuit configured to test an operation of the memory cell; and
a regulator configured to set a voltage of the word line or a cell power supply voltage of the memory cell to accelerate a disturb failure of the memory cell, based on an acceleration command from the self-test circuit.

2. The semiconductor memory device according to claim 1,
wherein the self-test circuit includes
a disturb acceleration commanding unit configured to output a disturb acceleration command for the memory cell to the regulator,
an address space reducing unit configured to reduce an address space of the memory cell to be tested by the self-test circuit, and
a fail bit determining unit configured to determine a fail bit of the memory cell tested by the self-test circuit.

3. The semiconductor memory device according to claim 1,
wherein the address space reducing unit selects a degenerate address such that accessed memory cells are distributed spatially uniformly.

4. The semiconductor memory device according to claim 3,
wherein the address space reducing unit degenerates a lower address.

5. The semiconductor memory device according to claim 2,
wherein a difference between the voltage of the word line and the cell power supply voltage is greater in a test mode than in a general use mode.

6. The semiconductor memory device according to claim 5,
wherein in the general use mode, the cell power supply voltage is set to be higher than a logical power supply voltage and the potential of the word line is set to be equal to or lower than the cell power supply voltage, and
in the test mode, the cell power supply voltage is set to be lower than a logical power supply voltage and the potential of the word line is set to be equal to the logical power supply voltage.

7. The semiconductor memory device according to claim 1,
wherein both the voltage of the word line and the cell power supply voltage are set to be lower when a read speed of the memory cell is high than when the read speed of the memory cell is low.

8. The semiconductor memory device according to claim 1,
wherein the voltage of the word line is set to be lower when a read speed of the memory cell is high than when the read speed of the memory cell is low, with the cell power supply voltage being constant.

9. The semiconductor memory device according to claim 2,
wherein a power save mode is provided that sets both the voltage of the word line and the cell power supply voltage to be lower when a read speed of the memory cell is high than when the read speed of the memory cell is low,
a disturb margin improvement mode is provided that sets the voltage of the word line to be lower when the read speed is high than when the read speed is low, with the cell power supply voltage being constant, and
the power save mode or the disturb margin improvement mode is selected according to a fluctuation in characteristics of the memory cell.

10. The semiconductor memory device according to claim 9,
wherein the fluctuation in the characteristics of the memory cell is estimated from a disturb failure occurrence rate of the memory cell.

11. The semiconductor memory device according to claim 10,
wherein when the number of fail bits of the memory cell exceeds a predetermined value, the fail bit determining unit determines that the disturb failure occurrence rate of the memory cell is high, and when the number of fail bits of the memory cell is equal to or smaller than the predetermined value, the fail bit determining unit determines that the disturb failure occurrence rate of the memory cell is low.

12. The semiconductor memory device according to claim 1,
wherein the memory cell includes
a first CMOS inverter that includes a first drive transistor and a first load transistor connected in series to each other,
a second CMOS inverter that includes a second drive transistor and a second load transistor connected in series to each other,
a first transfer transistor that is connected between a first bit line and a first storage node provided at a connection point between the first drive transistor and the first load transistor, and
a second transfer transistor that is connected between a second bit line and a second storage node provided at a connection point between the second drive transistor and the second load transistor,
wherein inputs and outputs of the first CMOS inverter and the second CMOS inverter are cross-coupled with each other, and
a gate of the first transfer transistor and a gate of the second transfer transistor are connected to the word line.

13. The semiconductor memory device according to claim 1, comprising a row decoder configured to select the word line supplied with the voltage of the word line.

14. The semiconductor memory device according to claim 13, comprising a column decoder configured to select a memory cell column designated by a column address.

15. The semiconductor memory device according to claim 14,
wherein the column decoder includes a sense amplifier circuit configured to detect the data stored in the memory cell, based on a signal read from the memory cell to the bit line.

16. The semiconductor memory device according to claim 15, comprising a dummy cell configured to set a timing of activating the sense amplifier circuit.

17. The semiconductor memory device according to claim 16, comprising a precharge transistor configured to precharge the bit line.

18. The semiconductor memory device according to claim 16,
wherein a dummy cell power supply voltage of the dummy cell is controlled in conjunction with the cell power supply voltage.

19. The semiconductor memory device according to claim 18,
wherein the dummy cell power supply voltage is set to a potential that is lower than the word line voltage and the cell power supply voltage by a predetermined voltage.

20. The semiconductor memory device according to claim 19,
wherein the dummy cell power supply voltage is set to a value that is lower than the word line voltage and the cell power supply voltage by a predetermined voltage corresponding to a random fluctuation of the memory cell.
